(19) United States
(12) Patent Application Publication
(10) Pub. No.: US 2023/0168299 A1
(43) Pub. Date: Jun. 1, 2023

(54) DEVICES AND METHODS FOR TESTING OF FAR-FIELD WIRELESS CHARGING

(71) Applicant: Rohde & Schwarz GmbH & Co. KG, Munich (DE)

(72) Inventors: Daniela RADDINO, Munich (DE); Rania MORSI, Unterhaching (DE)

(21) Appl. No.: 17/973,276

(22) Filed: Oct. 25, 2022

(30) Foreign Application Priority Data
Nov. 26, 2021 (EP) 21 210 681.9

(51) Int. Cl. G01R 31/302; G01R 31/319; H02J 50/40

(52) U.S. Cl. CPC G01R 31/3025; G01R 31/31908; H02J 50/40

(57) ABSTRACT

Disclosed is a device for testing of far-field wireless charging, including a first transceiver configured to conduct a far-field wireless power transfer between the device and a device under test, DUT; a second transceiver configured to conduct a data transfer between the device and the DUT; and a processor configured to establish a figure of merit of a wireless charging of the DUT in dependence of the power transfer and the data transfer.

### TECHNICAL FIELD

The present disclosure relates to testing of a variant of wireless charging involving far-field wireless power transfer, and in particular, to devices and methods for testing of such far-field wireless charging.

### BACKGROUND ART

Ongoing power supply of wireless electronic devices typically involves repeated manual recharging or battery replacement. For a great deal of more recent wireless electronic devices, such an approach is impractical. This particularly applies to devices or chipsets for the Internet of Things (IoT).

The alternative of wireless charging has gained significant market momentum, especially for bridging a charging gap of up to several centimeters by near-field wireless charging charging variants involving capacitive coupling via electric fields or inductive coupling via magnetic fields. A far-field charging variant, bridging up to several meters, is less widespread for its limited power transfer capacity, but still attracting interest in particular deployments of an abundance of devices which are difficult to access, for example.

When implementing far-field wireless charging, device manufacturers require the means to verify associated device capabilities and device conformity with applicable standards and regulation.

### SUMMARY

In view of the above, the present disclosure aims to provide such testing means. This is achieved by the subject-matter defined by the appended independent claims. Preferred embodiments are set forth in the dependent claims and in the following description and drawings.

A first aspect of the present disclosure relates to a device for testing of far-field wireless charging. The device includes a first transceiver configured to conduct a far-field wireless power transfer between the device and a device under test (DUT); a second transceiver configured to conduct a data transfer between the device and the DUT; and a processor configured to establish a figure of merit of a wireless charging of the DUT in dependence of the power transfer and the data transfer.

The far-field wireless power transfer between the device and the DUT may exceed a Fraunhofer distance.

The first transceiver may further be configured for beamforming of the far-field wireless power transfer.

The second transceiver may include one of: a wireless transceiver; and a wired transceiver.

The data transfer may include one of: a receive power of the DUT due to the power transfer; a battery charge power of the DUT due to the power transfer; a battery DC level of the DUT; and a battery state of charge of the DUT.

The data transfer may include: a transmit power of the DUT due to the power transfer.

The figure of merit of the DUT may include one of: a compliance of the transmit power of the DUT with a preset transmit power at a preset frequency; and a charging efficiency of the DUT in dependence of the transmit power of the DUT.

The figure of merit of the DUT may include at least one of: a charging efficiency of the DUT over time; a charging efficiency of the DUT in dependence of a relative distance between the device and the DUT; a charging efficiency of the DUT in dependence of a relative orientation between the device and the DUT; a charging efficiency of the DUT in dependence of a relative motion between the device and the DUT; a charging efficiency of the DUT in dependence of a preset channel condition between the device and the DUT; a charging efficiency of the DUT in dependence of a simultaneous wireless data transfer of the first transceiver; a charging efficiency of the DUT in dependence of a simultaneous wireless transmission in a frequency range of the first transceiver; and a charging efficiency of the DUT in dependence of a waveform of the power transfer.

The relative orientation may include an angle of arrival, AoA, or an angle of departure, AoD, of the DUT.

The preset channel condition may include one or more of: a fading profile; an outdoor condition; and an indoor condition.

The processor may further be configured to trigger the simultaneous wireless transmission; and the simultaneous wireless transmission may include a Bluetooth, WiFi, cellular or ambient transmission.

A second aspect of the present disclosure relates to a method for testing of far-field wireless charging. The method includes: conducting a far-field wireless power transfer between the device and a DUT; conducting a data transfer between the device and the DUT; and establishing a figure of merit of a wireless charging of the DUT in dependence of the power transfer and the data transfer.

The method may be performed by a device for testing of far-field wireless charging as defined above.

### Advantageous Effects

The present disclosure provides devices and methods for testing of far-field wireless charging, which ensures proper operation of DUTs involved in the charging, and conformity of said DUTs with applicable standards and regulation.

Testing of a charge-receiving DUT may advantageously cover aspects such as:
Charging quality of the DUT
Charging while moving/rotating
Coexistence testing
Charging under different channel conditions
Charging level over time
Charging efficiency of the DUT for different transmit waveforms
Charging range
Simultaneous data reception or transmission while charging.

Testing of a charge-transmitting DUT may advantageously cover aspects such as:
DUT transmitted directivity
Charging support for multiple simultaneous receiver devices
Charging support for multiple charging rates
Power transfer efficiency of the transmitting DUT
Charging efficiency in dependence of the transmitted waveform
Simultaneously transmitting power & data
Coexistence tests
Standard compliance
Regulatory testing

### BRIEF DESCRIPTION OF DRAWINGS

The above-described aspects and implementations will now be explained with reference to the accompanying drawings, in which the same or similar reference numerals designate the same or similar elements.

The features of these aspects and implementations may be combined with each other unless specifically stated otherwise.

The drawings are to be regarded as being schematic representations, and elements illustrated in the drawings are not necessarily shown to scale. Rather, the various elements are represented such that their function and general purpose become apparent to those skilled in the art.

FIGS. 1 and 2 illustrate respective devices for testing of far-field wireless charging in accordance with the present disclosure;

FIGS. 3 and 4 respectively illustrate testing subject to a relative orientation between the respective device and its DUT;

FIG. 5 illustrates testing subject to preset channel conditions between the device and its DUT;

FIG. 6 illustrates testing subject to a simultaneous wireless data transfer of the first transceiver and/or a simultaneous wireless transmission in a frequency range of the first transceiver; and

FIG. 7 illustrates a method for testing of far-field wireless charging in accordance with the present disclosure.

### DETAILED DESCRIPTIONS OF DRAWINGS

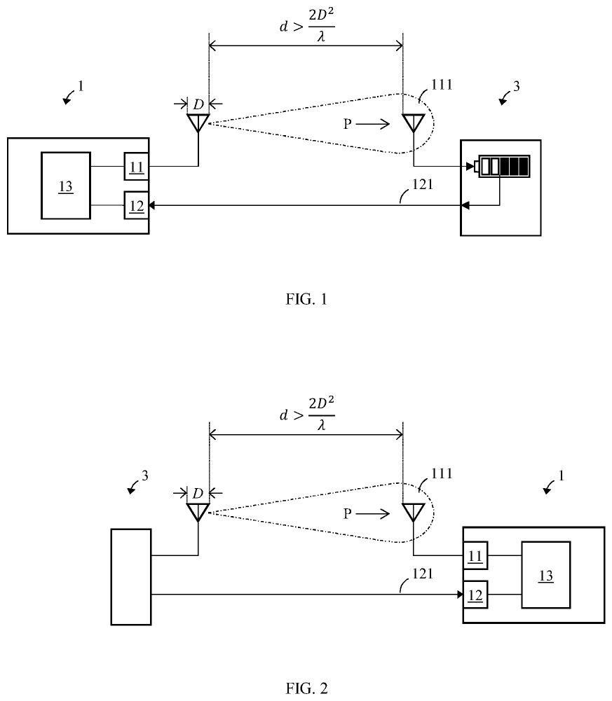

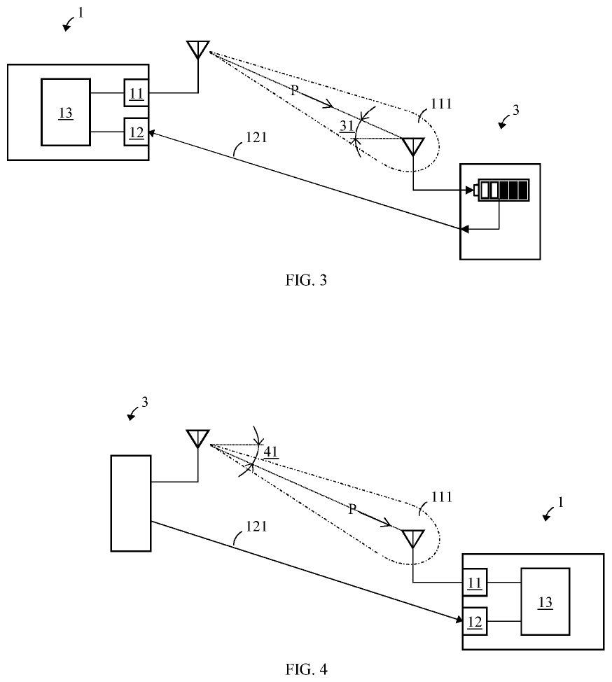

FIGS. 1 and 2 illustrate respective devices 1 for testing of far-field wireless charging in accordance with the present disclosure.

With reference to both FIG. 1 and FIG. 2, the respective device 1 includes a first transceiver 11 configured to conduct a far-field wireless power transfer 111, P between the device 1 and a device under test, DUT 3.

The far-field wireless power transfer 111, P between the device 1 and the DUT 3 may exceed a Fraunhofer distance of d=2D²/λ, wherein D represents a largest dimension of a radiator (i.e., transmit antenna) involved in the power transfer 111, P, and λ is a wavelength of the radiated radio wave. The Fraunhofer distance defines the limit between the near field and the far field. The far field is characterized by propagating electromagnetic waves.

In particular, the first transceiver 11 may further be configured for beamforming of the far-field wireless power transfer 111, P. Beamforming or spatial filtering as used herein may refer to a signal processing technique used in antenna arrays for directional signal transmission or reception. Beamforming can be used at both the transmitting and receiving ends in order to achieve directivity (i.e., spatial selectivity). Those skilled in the art will readily appreciate that in the case of beamforming the individual antennas indicated in FIGS. 1 and 2 actually stand for antenna arrays. A directivity of the respective power transfer 111, P is indicated by a respective schematic main lobe.

The respective device 1 further includes a second transceiver 12 configured to conduct a data transfer 121 between the device 1 and the DUT 3.

The second transceiver 12 may include one of: a wireless transceiver (not shown); and a wired transceiver (see FIGS. 1 to 6).

For example, the data transfer 121 may be realized by means of a potentially standardized protocol. Alternatively, the data transfer 121 may be realized by direct measurement of the respective electric quantity of the DUT 3 by the device 1.

According to both FIG. 1 and FIG. 2, the data transfer 121 is directed towards the device 1. However, there may also be an optional data transfer (not shown) from the device 1 to the DUT 3. For example, this further data transfer may involve sending control signals needed for charging purposes, or sending communication signals to the DUT 3.

The respective device 1 further includes a processor 13 configured to establish a figure of merit of a wireless charging of the DUT 3 in dependence of the power transfer 111, P and the data transfer 121.

Upon testing of charge-receiving DUTs 3 (see FIG. 1), the data transfer 121 may include one of: a receive power of the DUT 3 due to the power transfer 111, P; a battery charge power of the DUT 3 due to the power transfer 111, P; a battery direct current (DC) level of the DUT 3; and a battery state of charge of the DUT 3. The established figure of merit of the DUT 3 may include a charging efficiency of the DUT 3 in dependence of a transmit (RF) power of the device 1 due to the power transfer 111, P.

As used herein, an efficiency may generally refer to a ratio of useful output to total input, and a charging efficiency may correspondingly refer to a ratio of an indication of charging output/achievement to an indication of charging input/effort.

As such, the figure of merit of the charge-receiving DUT 3 of FIG. 1 may include one of:
a ratio of the receive power of the DUT 3 due to the power transfer 111 and the transmit RF power of the device 1,
a ratio of the battery charge power (i.e., charging DC power) of the DUT 3 due to the power transfer 111 and the transmit RF power of the device 1,
a ratio of an increase in the battery DC level (ΔV_{DC}) of the DUT 3 due to the power transfer 111 and the transmit RF power of the device 1, and—
a ratio of an increase in the battery state of charge (ΔSOC) of the DUT 3 due to the power transfer 111 and the transmit RF power of the device 1.

In other words, when testing the charge-receiving DUT 3 of FIG. 1, the overall charging efficiency may be calculated as a ratio of the charging DC power at the receiving DUT 3 and the transmit RF power at the transmitting device 1.

The overall charging efficiency may be determined as a product of an RF-to-RF efficiency over the air and an RF-to-DC efficiency of the DUT 3.

The RF-to-RF efficiency is a ratio of a received RF power at the receiving DUT 3 and a transmit RF power at the transmitting device 1, and may depend on a relative distance d between the device 1 and the DUT 3, or on a frequency of the power transfer 111, for example.

The RF-to-DC efficiency is a ratio of the charging DC power at the receiving DUT 3 and the received RF power at the receiving DUT 3, and may depend on an RF-to-DC conversion circuit of the DUT 3, or on a waveform (i.e., shape) of the power transfer 111, for example.

Upon testing of charge-transmitting DUTs 3 (see FIG. 2), the data transfer 121 may include: a transmit (RF) power of the DUT 3 due to the power transfer 111, P. The established figure of merit of the DUT 3 may include one of: a compliance of the transmit RF power of the DUT 3 with a preset transmit power at a preset frequency; and a charging efficiency of the DUT 3 in dependence of the transmit RF power of the DUT 3.

In other words, when testing the charge-transmitting DUT 3 of FIG. 2, then the overall charging efficiency may be calculated as a ratio between the charging DC power at the receiving device 1 and the transmit RF power of the transmitting DUT 3.

For example, the compliance of the transmit power of the DUT 3 with a preset transmit power at a preset frequency may be established by a frequency sweep through a spectral mask defining a preset transmit power at a respective preset frequency and verifying that the transmit power of the DUT 3 does not project beyond the spectral mask. The established figure of merit may correspond to a binary value indicating that the compliance test has (not) been passed successfully, for instance.

For example, the charging efficiency of the DUT 3 in dependence of the transmit power of the DUT 3 may be established by: dividing a receive power of the device 1 due to the power transfer 111, P by the communicated transmit power of the DUT 3 due to the power transfer 111, P.

Upon testing of charge-receiving DUTs 3 (see FIG. 1) or charge-transmitting DUTs 3 (see FIG. 2), the figure of merit of the DUT 3 may include at least one of: a charging efficiency of the DUT 3 over time; a charging efficiency of the DUT 3 in dependence of a relative distance d between the device 1 and the DUT 3; a charging efficiency of the DUT 3 in dependence of a relative orientation between the device 1 and the DUT 3; a charging efficiency of the DUT 3 in dependence of a relative motion between the device 1 and the DUT 3; a charging efficiency of the DUT 3 in dependence of a preset channel condition between the device 1 and the DUT 3; a charging efficiency of the DUT 3 in dependence of a simultaneous wireless data transfer of the first transceiver 11; a charging efficiency of the DUT 3 in dependence of a simultaneous wireless transmission 61 in a frequency range of the first transceiver 11; and a charging efficiency of the DUT 3 in dependence of the waveform of the power transfer 111.

For example, the charging efficiency of the DUT 3 over time may be established by recording individually established charging efficiency values as a function of the applicable recording time.

For example, the charging efficiency of the DUT 3 in dependence of a relative distance d between the device 1 and the DUT 3 may be established by recording individually established charging efficiency values as a function of the applicable relative distance d between the device 1 and the DUT 3.

For example, the charging efficiency of the DUT 3 in dependence of a relative motion between the device 1 and the DUT 3 may be established by recording individually established charging efficiency values as a function of the applicable relative motion (i.e., velocity, acceleration, rotation, . . . ) between the device 1 and the DUT 3.

FIGS. 3 and 4 respectively illustrate testing subject to a relative orientation between the respective device 1 and its DUT 3.

For example, the charging efficiency of the DUT 3 in dependence of the relative orientation between the device 1 and the DUT 3 may be established by recording individually established charging efficiency values as a function of the applicable relative orientation between the device 1 and the DUT 3.

In particular, the relative orientation may include an angle of arrival, AoA 31 (see FIG. 3), or an angle of departure, AoD 41 (see FIG. 4), of the DUT 3.

FIG. 5 illustrates testing subject to preset channel conditions between the device 1 and its DUT 3;

For example, the charging efficiency of the DUT 3 in dependence of a preset channel condition between the device 1 and the DUT 3 may be established by recording individually established charging efficiency values as a function of the applicable preset channel condition between the device 1 and the DUT 3.

In particular, the preset channel condition may include one or more of: a fading profile; an outdoor condition; and an indoor condition.

FIG. 5 shows that an exemplary fading profile P(t) may be used as the preset channel condition to which the power transfer 111, P between the device 1 and the DUT 3 may be subjected, resulting in a time-variant power transfer 111, P(t). As such, the processor 13 may further be configured to simulate an exposure of the power transfer 111, P(t) between the device 1 and the DUT 3 to the preset channel conditions.

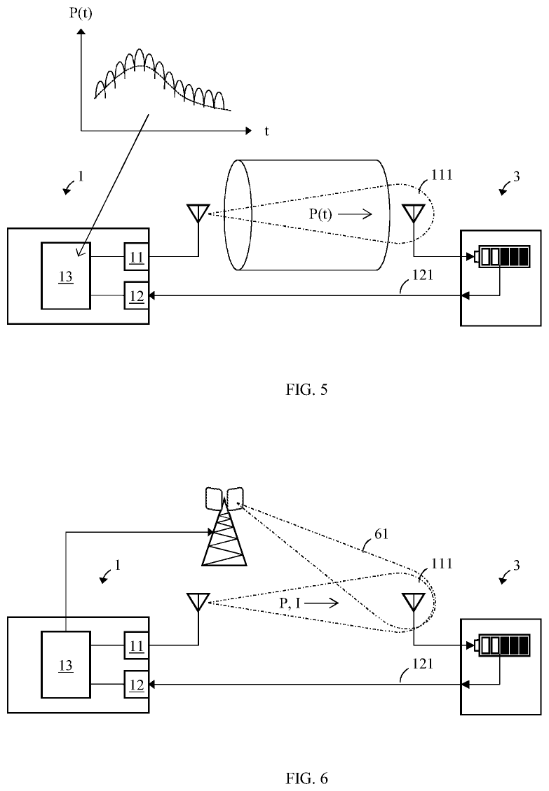

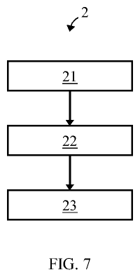

FIG. 6 illustrates testing subject to a simultaneous wireless data transfer I of the first transceiver and a simultaneous wireless transmission 61 in a frequency range of the first transceiver.

In this connection, the processor 13 may further be configured to activate the simultaneous wireless data transfer I of the first transceiver 11.

For example, the charging efficiency of the DUT 3 in dependence of the simultaneous wireless data transfer I of the first transceiver 11 may be established by recording individually established charging efficiency values in a presence or an absence of the simultaneous wireless data transfer I and averaging the charging efficiency values recorded in a presence of the simultaneous wireless data transfer I to obtain the corresponding charging efficiency of the DUT 3. By further averaging the charging efficiency values recorded in an absence of the simultaneous wireless data transfer I and forming a ratio of the averaged charging efficiency values for both cases, a change in the charging efficiency of the DUT 3 in a presence of the simultaneous wireless data transfer I may be determined.

Similarly, the charging efficiency of the DUT 3 in dependence of the simultaneous wireless transmission 61 in a frequency range of the first transceiver 11 may be established by recording individually established charging efficiency values in a presence or an absence of the simultaneous wireless transmission 61.

To this end, the processor 13 may further be configured to trigger the simultaneous wireless transmission 61. In other words, the simultaneous wireless transmission 61 may be conducted by the device 1 or preferably by an external source of radiation. The simultaneous wireless transmission 61 may include a Bluetooth, WiFi, cellular or ambient transmission (e.g., noise floor). Without limitation, an exemplary simultaneous cellular transmission 61 is suggested in FIG. 6. Of note, additional considerations may be required for reproducibility of testing results, such as a preset transmit power, a preset relative distance, a preset relative orientation etc. between the external source of radiation and the DUT 3.

In general, considering interfering signals in a same frequency range of a transmit signal may have the following effects: On the one hand, an interfering signal may be disadvantageous to a communication signal making it more difficult at the receiver to extract the information from the communication signal. On the other hand, an interfering signal may advantageously add power on top of a transmitted power transfer 111.

The charging efficiency of the DUT 3 in dependence of the waveform (i.e., pulse shape) of the power transfer 111 may be established by recording individually established charging efficiency values at the DUT 3 for different waveforms (e.g., constant-envelope sinusoidal signal, multi-sine signals with different number of frequency tones, with different amplitude and phase for each tone, signals with different peak-to-average-power ratios, etc.).

FIG. 7 illustrates a method 2 for testing of far-field wireless charging in accordance with the present disclosure.

The method 2 includes: conducting 21 a far-field wireless power transfer 111, P between the device 1 and a DUT 3; conducting 22 a data transfer 121 between the device 1 and the DUT 3; and establishing 23 a figure of merit of a wireless charging of the DUT 3 in dependence of the power transfer 111, P and the data transfer 121.

The method 2 may be performed by a device 1 for testing of far-field wireless charging as defined above.

1. A device for testing of far-field wireless charging, including
a first transceiver configured to conduct a far-field wireless power transfer between the device and a device under test, DUT;
a second transceiver configured to conduct a data transfer between the device and the DUT; and
a processor configured to establish a figure of merit of a wireless charging of the DUT in dependence of the power transfer and the data transfer.

2. The device of claim 1,
the far-field wireless power transfer between the device and the DUT exceeding a Fraunhofer distance.

3. The device of claim 1,
the first transceiver further configured for beamforming of the far-field wireless power transfer.

4. The device of claim 1,
the second transceiver including one of:
a wireless transceiver; and
a wired transceiver.

5. The device of claim 1,
the data transfer including one of:
a receive power of the DUT due to the power transfer;
a battery charge power of the DUT due to the power transfer;
a battery DC level of the DUT; and
a battery state of charge of the DUT.

6. The device of claim 1,
the data transfer including:
a transmit power of the DUT due to the power transfer.

7. The device of claim 6,
the figure of merit of the DUT including one of:
a compliance of the transmit power of the DUT with a preset transmit power at a preset frequency; and
a charging efficiency of the DUT in dependence of the transmit power of the DUT.

8. The device of claim 5,
the figure of merit of the DUT including at least one of:
a charging efficiency of the DUT over time;
a charging efficiency of the DUT in dependence of a relative distance between the device and the DUT;
a charging efficiency of the DUT in dependence of a relative orientation between the device and the DUT;
a charging efficiency of the DUT in dependence of a relative motion between the device and the DUT;
a charging efficiency of the DUT in dependence of a preset channel condition between the device and the DUT;
a charging efficiency of the DUT in dependence of a simultaneous wireless data transfer of the first transceiver; and
a charging efficiency of the DUT in dependence of a simultaneous wireless transmission in a frequency range of the first transceiver; and
a charging efficiency of the DUT in dependence of a waveform of the power transfer.

9. The device of claim 8,
the relative orientation including an angle of arrival, AoA, or an angle of departure, AoD, of the DUT.

10. The device of claim 8,
the preset channel condition including one or more of:
a fading profile;
an outdoor condition; and
an indoor condition.

11. The device of claim 8,
the processor further configured to trigger the simultaneous wireless transmission;
the simultaneous wireless transmission including a Bluetooth, WiFi, cellular or ambient transmission.

12. A method for testing of far-field wireless charging, including
conducting a far-field wireless power transfer between the device and a device under test, DUT;
conducting a data transfer between the device and the DUT; and
establishing a figure of merit of a wireless charging of the DUT in dependence of the power transfer and the data transfer.

13. The method of claim 12, wherein the device comprises:
a first transceiver configured to conduct a far-field wireless power transfer between the device and a device under test, DUT;
a second transceiver configured to conduct a data transfer between the device and the DUT; and
a processor configured to establish a figure of merit of a wireless charging of the DUT in dependence of the power transfer and the data transfer.
